(19) United States
(12) Patent Application Publication
(10) Pub. No.: US 2012/0234375 A1
(43) Pub. Date: Sep. 20, 2012

(54) THIN FILM SOLAR CELL AND METHOD OF MANUFACTURING THE SAME

(75) Inventors: Keisuke Nakamura, Tokyo (JP); Hidetada Tokioka, Tokyo (JP); Takeo Furuhata, Tokyo (JP)

(73) Assignee: Mitsubishi Electric Corporation, Tokyo (JP)

(21) Appl. No.: 13/508,429

(22) PCT Filed: Apr. 8, 2010
(86) PCT No.: PCT/JP2010/056401

§ 371 Date: May 7, 2012

(30) Foreign Application Priority Data
Nov. 17, 2009 (JP) 2009-262162

(51) Int. Cl. H01L 31/05; H01L 31/18

(52) U.S. Cl. 136/249; 438/80; 257/E31.124

(57) ABSTRACT

A thin film solar cell includes, on a substrate, a first electrode layer formed of a transparent conductive material, a photoelectric conversion layer, and a second electrode layer including a conductive material that reflects light. The thin film solar cell includes a plurality of unit solar battery cells divided by scribe lines. The second electrode layer and the first electrode layer of the unit solar battery cell adjacent to the second electrode layer are connected in the scribe line formed in the photoelectric conversion layer. The unit solar battery cells are electrically connected in series. The scribe lines on both sides of at least one of the unit solar battery cells are formed such that the unit solar battery cell held between the scribe lines meanders while having fixed width in a predetermined direction and have same shapes that overlap when the scribe lines translate in the predetermined direction.

The present invention relates to a thin film solar cell and a method of manufacturing the thin film solar cell.

### BACKGROUND

A photovoltaic power generation system is prospective as clean energy for protecting the earth environment in the twenty-first century from an increase in CO₂ gas caused by the burning of fossil energy. A production quantity of the fossil energy is increasing explosively. This causes a situation in which silicon wafers are in short supply all over the world. Therefore, in recent years, a production quantity of a thin film solar cell, a photoelectric conversion layer (a semiconductor layer) of which is made of a thin film, not rate-limited by a supply amount of silicon wafers is rapidly increasing.

In the thin film solar cell, a transparent electrode of a thin film, a photoelectric conversion layer, and a metal electrode made are directly formed on a substrate having a large area of about a meter square by a sputtering method, an evaporation method, a CVD (Chemical Vapor Deposition) method, or the like. However, because the resistivity of the electrodes, in particular, the transparent electrode is high, in general, a configuration for dividing the entire large-area substrate into a plurality of unit solar battery cells and sequentially connecting the unit solar battery cells in series to thereby increase a voltage and extract energy while limiting a current amount is adopted. Further, a thin film solar cell is proposed that has structure in which all scribe lines for dividing a unit cell are formed to be bent in a triangular wave shape and the scribe lines adjacent to one another are respectively shifted by a half wavelength, whereby intervals among the adjacent scribe lines are repeatedly expanded and reduced with respect to one another (see, for example, Patent Literature 1). An overall resistance loss is reduced by feeding a large amount of electric currents to a section where the intervals among the scribe lines are reduced, a distance of the transparent electrode is short, and an electric resistance is small.

### CITATION LIST

### Patent Literature

Patent Literature 1: Japanese Patent No. 3172369

### SUMMARY

### Technical Problem

A transparent conductive material thin film forming a transparent electrode on a light incident side used in a thin film solar cell generally has high sheet resistance. When an electric current flows a long distance in the transparent electrode, a power generation efficiency falls because of Joule losses of the electric current.

Therefore, to reduce a current path, the width of one unit solar battery cell having the photoelectric conversion layer is generally limited to 4 millimeters to 20 millimeters.

In Patent Literature 1, the width of the unit cell is expanded and reduced and a large amount of electric currents are fed to a section where the current path is short in the transparent electrode to reduce the overall resistance loss. However, there are drawbacks in that, in a section where the width of the unit cell is expanded, the current path in the transparent electrode could be long compared with that in a unit cell formed by scribe lines parallel to one another, the Joule losses increase because the electric currents concentrate near vertexes of the scribe lines bent in a triangular wave shape and electric field intensity increases in a section where the electric currents concentrate, and, when a shape for expanding and reducing the width of the unit cell is adopted as in Patent Literature 1, because minimum width of the unit cell has to be a positive value, the scribe lines cannot be bent so largely compared with bending of the scribe lines in the unit cell formed by the scribe lines parallel to one another.

The present invention has been devised in view of the above and it is an object of the present invention to obtain a thin film solar cell in which a laminated body including a transparent electrode, a photoelectric conversion layer, and a metal electrode is formed on a substrate, the thin film solar cell being capable of suppressing Joule losses in the transparent electrode and improving power generation efficiency compared with the related art, and a method of manufacturing the thin film solar cell.

### Solution to Problem

In order to achieve the above-mentioned objects of the present invention, a thin film solar cell according to the present invention including: a first electrode layer formed of a transparent conductive material; a photoelectric conversion layer; and a second electrode layer including a conductive material that reflects light, the first electrode layer, the photoelectric conversion layer, and the second electrode layer being formed on a substrate, the thin film solar cell including a plurality of unit cells divided by grooves, and the second electrode layer and the first electrode layer of the unit cell adjacent to the second electrode layer being connected in the groove formed in the photoelectric conversion layer and the unit cells being electrically connected in series, wherein the grooves on both sides of at least one of the unit cells are formed such that the unit cell held between the grooves meanders while having fixed width in a predetermined direction and have same shapes that overlap when the grooves translate in the predetermined direction.

### Advantageous Effects of Invention

According to the present invention, the grooves on both the sides of at least one unit solar battery cell are formed such that the unit solar battery cell held between the grooves meanders while having the fixed width in the predetermined direction and are formed to have the same shapes that overlap when the unit solar battery cell is translated in the predetermined direction. Therefore, compared with solar battery cells separated by linear scribe lines with the same cell width, a current path in a part of a region can be reduced. As a result, there is an effect that it is possible to suppress Joule losses in transparent electrodes of the unit solar battery cells and improve power generation efficiency compared with the related art.

Further, there are many advantages, for example, there is no section where an electric path in the transparent electrode is long compared with a unit cell formed by linear scribe lines parallel to one another, Joule losses due to an increase in electric field intensity caused by current concentration can be reduced because an amount of concentration of electric currents near bending points of scribe lines can be suppressed compared with Patent Literature 1, and the scribe lines can be bent more largely compared with Patent Literature 1.

### BRIEF DESCRIPTION OF DRAWINGS

FIG. 1 is a top view of an example of a thin film solar cell according to a first embodiment of the present invention.

FIG. 2 is a partial sectional view on line A-A in FIG. 1.

FIG. 3-1 is a first schematic sectional view of an example of a procedure of a method of manufacturing a thin film solar cell according to the first embodiment.

FIG. 3-2 is a second schematic sectional view of the example of the procedure of the method of manufacturing a thin film solar cell according to the first embodiment.

FIG. 3-3 is a third schematic sectional view of the example of the procedure of the method of manufacturing a thin film solar cell according to the first embodiment.

FIG. 3-4 is a fourth schematic sectional view of the example of the procedure of the method of manufacturing a thin film solar cell according to the first embodiment.

FIG. 3-5 is a fifth schematic sectional view of the example of the procedure of the method of manufacturing a thin film solar cell according to the first embodiment.

FIG. 3-6 is a sixth schematic sectional view of the example of the procedure of the method of manufacturing a thin film solar cell according to the first embodiment.

FIG. 4 is a schematic diagram of an example of the shape of scribe lines according to the first embodiment.

FIG. 5 is a schematic diagram of a state in which electric currents flow in a transparent electrode layer corresponding to a parallelogram region.

FIG. 6 is a graph of a relation between dS/dx and x respectively normalized by L and D when θ=π/4 and L/D=2.

FIG. 7 is a schematic diagram of a state of electric currents flow in a transparent electrode layer corresponding to a parallelogram region.

FIG. 8 is a graph in which a relation between dS/dx and x respectively normalized by L and D when θ=π/4 and L/D=1/3.

FIG. 9 is a table of an example of a relation of a ratio J/J₀ of Joule losses between a case of bent scribe lines and a case of non-bent scribe lines at a time when L/D and θ are changed.

FIG. 10 is a top view of another example of the configuration of the thin film solar cell according to the first embodiment.

FIG. 11 is a top view of still another example of the configuration of the thin film solar cell according to the first embodiment.

FIG. 12 is a top view of still another example of the configuration of thin film solar cell according to the first embodiment.

FIG. 13 is a schematic top view of the structure of a thin film solar cell according to Patent Literature 1.

FIG. 14 is a schematic diagram of an example of the shape of scribe lines according to Patent Literature 1.

FIG. 15 is a schematic diagram of comparison of a state in which electric currents flow in a transparent electrode layer corresponding to a trapezoidal region of the thin film solar cell according to Patent Literature 1 and a state in which electric currents flow in a transparent electrode layer corresponding to a parallelogram region of the thin film solar cell according to the first embodiment.

FIG. 16 is a top view of an example of a thin film solar cell according to a second embodiment of the present invention.

FIG. 17 is a top view of an example of a thin film solar cell according to a third embodiment of the present invention.

FIG. 18 is a schematic top view of an example of a configuration for extracting an electric current from the thin film solar cell shown in FIG. 17.

### DESCRIPTION OF EMBODIMENTS

Thin film solar cells and a method of manufacturing the thin film solar cells according to embodiments of the present invention are explained in detail below with reference to the accompanying drawings. The present invention is not limited by these embodiments. Sectional views of the thin film solar cells used in the embodiments are schematic. A relation between the thickness and the width of a layer, a ratio of the thicknesses of layers, and the like are different from actual ones.

### First Embodiment

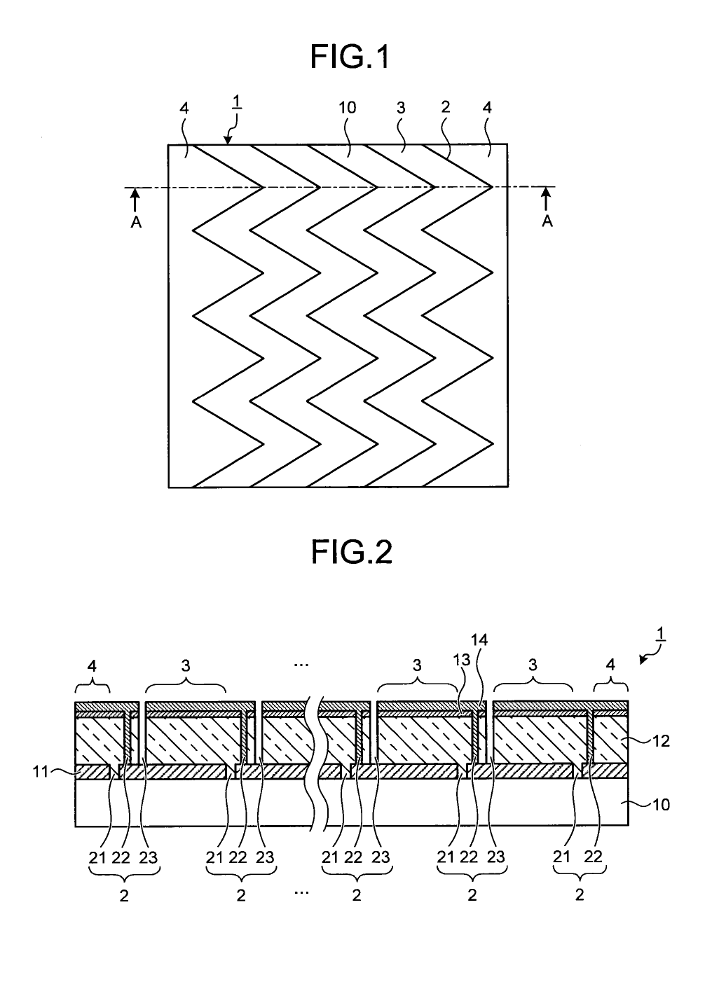

FIG. 1 is a top view of an example of a thin film solar cell according to a first embodiment of the present invention. A thin film solar cell 1 according to the first embodiment functions as a thin film solar cell module as a whole because a plurality of unit solar battery cells 3 are connected in series and integrated on an insulated translucent substrate 10 having a rectangular shape. Electric currents led to current extracting sections 4 at both ends are extracted to the outside. The unit solar battery cells 3 are separated by scribe lines 2, which are separation grooves. The unit solar battery cells 3 and the current extracting sections 4 are also separated by the scribe lines 2. The shape of the scribe lines 2 is a bent shape in which a combination of line segments tilting with respect to end faces of the insulated translucent substrate 10 is periodically repeated. The scribe lines 2 adjacent to one another are arranged substantially in parallel. The unit solar battery cells 3 have a shape in which a direction along the scribe lines 2 is longitudinal compared with intervals among the adjacent scribe lines 2. Positions in the longitudinal direction of bending sections in the scribe lines 2 are set in substantially the same positions in all the scribe lines 2.

In other words, the separation grooves (the scribe lines 2) on both sides of the unit solar battery cells 3 are formed in the same meandering shapes that overlap each other when the separation grooves are translated in a direction along one side of the rectangular insulated translucent substrate 10. Consequently, the unit solar battery cell 3 held between the separation grooves are formed in a shape that meanders such that the width in the direction along the one side of the insulated translucent substrate 10 is substantially fixed. In another expression, when the separation grooves are formed in a wavy shape, a plurality of waves are formed in shapes arranged in parallel in an amplitude direction of the waves to have the same phase at substantially the same intervals.

The shape of the insulated translucent substrate 10 is the rectangular shape. However, the shape of the insulated translucent substrate 10 is not limited to the rectangular shape and can be other shapes. In that case, the separation grooves on both the sides of the unit solar battery cell 3 only have to be set in a positional relation in which the separation grooves overlap each other when the separation grooves are translated in a specific direction.

FIG. 2 is a partial sectional view on line A-A in FIG. 1. As shown in the figure, in the thin film solar cell 1, a front surface electrode layer 11, a photoelectric conversion layer 12, an intermediate conductor layer 13, and a rear surface electrode layer 14 are stacked in order on the insulated translucent substrate 10. The unit solar battery cells 3 and the current extracting sections 4 are formed by the scribe lines 2 provided in predetermined positions. To extract electric currents generated in the thin film solar cell 1 to the outside, the electrode extracting sections 4 are provided to connect a wire on the outside and the thin film solar cell 1. For example, the rear surface electrode layer 14 of the current extracting sections 4 and a not-shown bus wire for extracting electric currents to the outside are connected. The photoelectric conversion layer 12 of the current extracting sections 4 does not contribute to power generation.

As the insulated translucent substrate 10, a glass material having high light transmittance such as white plate glass or a translucent organic film material such as polyimide can be used. The front surface electrode layer 11 only has to be a transparent conductive film having optical transparency. A transparent conductive oxide film of zinc oxide (ZnO), indium tin oxide (hereinafter referred to as ITO), or tin oxide (SnO₂) or a ZnO film, an ITO film, an SnO₂ film, or the like containing, as a dopant, at least one or more kinds of elements selected out of aluminum (Al), gallium (Ga), indium (In), boron (B), yttrium (Y), silicon (Si), zirconium (Zr), titanium (ti), fluorine (F), nitrogen (N), and the like can be used. The front surface electrode layer 11 can be a transparent conductive film formed by stacking these films. Further, the front surface electrode layer 11 desirably has a surface texture structure, on the surface of which unevenness is formed. This texture structure has a function of scattering the incident sunlight and improving light usage efficiency in the photoelectric conversion layer 12.

The photoelectric conversion layer 12 has pn junctions or pin junctions and is formed by stacking one or more thin film semiconductor layers that perform power generation with incident light. As such a photoelectric conversion layer 12, a semiconductor layer such as an amorphous silicon layer, a crystallite silicon layer, a hydrogenated amorphous silicon germanium layer, or a crystallite silicon germanium layer or a laminated body of these semiconductor layers can be used.

When the photoelectric conversion layer 12 is formed by stacking a plurality of thin film semiconductor layers, an intermediate layer formed of a conductive oxide material such as SnO₂, ZnO, or ITO or a material obtained by adding metal to these conductive oxide materials, or one or more kinds of materials selected out of p-type hydrogenated crystal silicon, i-type hydrogenated crystal silicon, n-type hydrogenated crystal silicon, a p-type hydrogenated amorphous silicon oxide, an i-type hydrogenated amorphous silicon oxide, an n-type hydrogenated amorphous silicon oxide, a p-type hydrogenated crystallite silicon oxide, an i-type hydrogenated crystallite silicon oxide, an n-type hydrogenated crystallite silicon oxide, p-type hydrogenated crystallite silicon carbide, i-type hydrogenated crystallite silicon carbide, and n-type hydrogenated crystallite silicon carbide can be inserted between different thin film semiconductor layers to improve electrical and optical connection between the different thin film semiconductor layers.

As the intermediate conductor layer 13, a transparent conductive film formed of a conductive oxide material such as SnO₂, ZnO, or ITO or a material obtained by adding metal to these conductive oxide materials, or one or more kinds of materials selected out of p-type hydrogenated crystal silicon, i-type hydrogenated crystal silicon, n-type hydrogenated crystal silicon, a p-type hydrogenated amorphous silicon oxide, an i-type hydrogenated amorphous silicon oxide, an n-type hydrogenated amorphous silicon oxide, a p-type hydrogenated crystallite silicon oxide, an i-type hydrogenated crystallite silicon oxide, an n-type hydrogenated crystallite silicon oxide, p-type hydrogenated crystallite silicon carbide, i-type hydrogenated crystallite silicon carbide, and n-type hydrogenated crystallite silicon carbide can be used.

As the rear surface electrode layer 14, a metal material having both high conductivity and light reflectivity such as silver (Ag), Al, Ti, gold (Au), copper (Cu), neodymium (Nd), or chrome (Cr) or a mixture of these metal materials can be used. A layer formed of these materials can be used as a single layer or can be stacked and used. A layer can be formed using the material in an interface section with the intermediate conductor layer 13. A layer formed of a material having low light reflectivity such as conductive paste can be further stacked on the layer.

The scribe lines 2 shown in FIG. 1 actually include first scribe lines 21 for separating the front surface electrode layer 11, second scribe lines 22 for separating the photoelectric conversion layer 12 and the intermediate conductor layer 13, and third scribe lines 23 for separating the photoelectric conversion layer 12, the intermediate conductor layer 13 and the rear surface electrode layer 14.

In a cross section of the thin film solar cell 1 shown in FIG. 2, a region held between the adjacent scribe lines 2 functions as the unit solar battery cell 3 and contributes to power generation. The unit solar battery cell 3 has a configuration in which the unit solar battery cell 3 is connected in series to the unit solar battery cell 3 adjacent thereto. Therefore, the unit solar battery cell 3 prevents the front surface electrode layer 11, the photoelectric conversion layer 12, the intermediate conductor layer 13, and the rear surface electrode layer 14 between the adjacent unit solar battery cells 3 from being connected. The unit solar battery cell 3 electrically connects the front surface electrode layer 11 of the own unit solar battery cell 3 and the rear surface electrode layer 14 of the unit solar battery cell 3 adjacent to one side and electrically connects the rear surface electrode layer 14 of the own unit solar battery cell 3 and the front surface electrode layer 11 of the unit solar battery cell 3 adjacent to the other side. Specifically, in FIG. 2, in a certain unit solar battery cell 3, the front surface electrode layer 11 is connected to the rear surface electrode layer 14 of the unit solar battery cell 3 adjacent to the left side and the rear surface electrode layer 14 is connected to the front surface electrode layer 11 of the unit solar battery cell 3 adjacent to the right side. Therefore, insulation among the adjacent unit solar battery cells 3 are secured by the first scribe lines 21 and the third scribe lines 23 and the front surface electrode layer 11 and the rear surface electrode layer 14 are set in contact with each other by the second scribe lines 22, whereby the adjacent unit solar battery cells 3 are connected in series. The thin film solar cell 1 functions as a solar cell module.

An overview of operation in the thin film solar cell 1 having such structure is explained. When sunlight is made incident from the rear surface (a surface on which the unit solar battery cells 3 are not formed) of the insulated translucent substrate 10, free carriers are generated in the photoelectric conversion layer 12. The generated free carriers are transported by an incorporated electric field formed by a p-type semiconductor layer and an n-type semiconductor layer of the photoelectric conversion layer 12 and electric currents are generated. The electric currents generated in the unit solar battery cells 3 flow into the adjacent unit solar battery cells 3 via the rear surface electrode layer 14 embedded in the second scribe lines 22. A power generation current of the entire thin film solar cell module is generated.

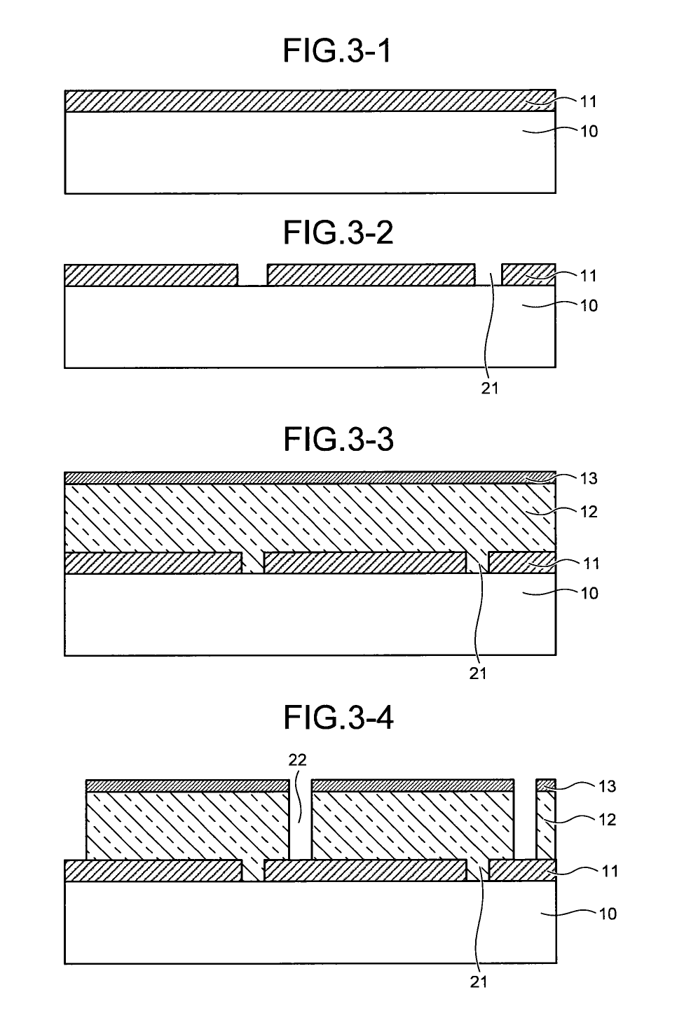

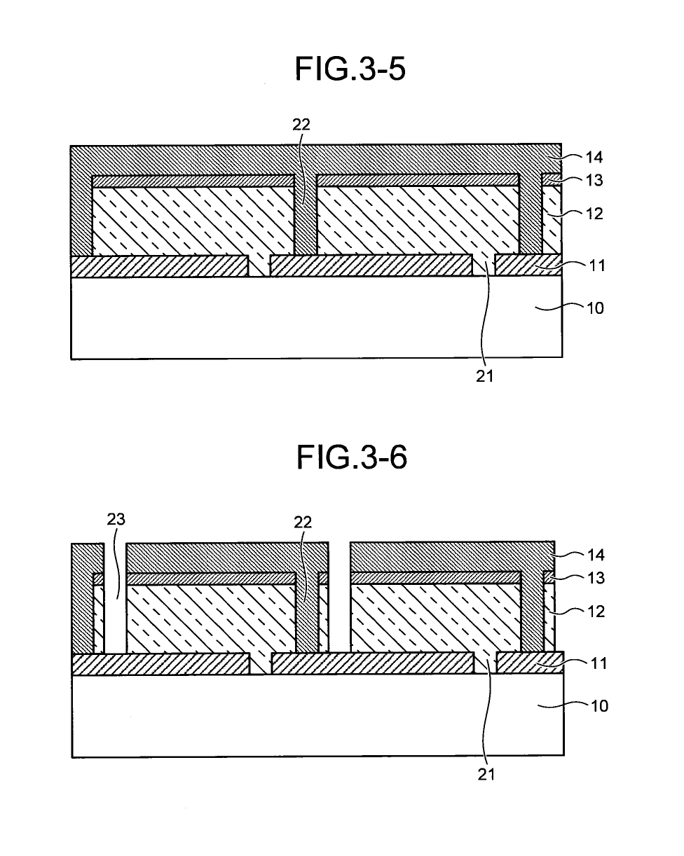

A method of manufacturing a thin film solar cell is explained. FIGS. 3-1 to 3-6 are schematic sectional views of an example of a procedure of a method of manufacturing a thin film solar cell according to the first embodiment. First, as shown in FIG. 3-1, the front surface electrode layer 11 is formed on the upper surface of the insulated translucent substrate 10 by a film forming method such as a sputtering method or a CVD method. After the front surface electrode layer 11 is formed, a surface texture structure can be formed using a wet etching method or a plasma etching method in which a solvent is used.

Subsequently, as shown in FIG. 3-2, the first scribe lines 21 for separating the front surface electrode layer 11 are formed by a laser processing method. Like the scribe lines 2 shown in FIG. 1, the first scribe lines 21 have a bent shape in plan view and are formed at predetermined intervals in a specific direction. The first scribe lines 21 adjacent to one another desirably have the same bent shape and are set parallel to one another such that positions of bending sections in a direction perpendicular to the specific direction are the same as one another. To form the first scribe lines 21, for example, the insulated translucent substrate 10 is placed on an XY stage of a laser processing apparatus and moved in an XY direction during laser processing. Consequently a desired bent shape can be obtained. Besides, the first scribe lines 21 having the desired bent shape can be formed by scanning a laser beam in an arbitrary position in an XY plane by galvanometer scanning. It is also possible to combine a moving state moving only in one direction and a laser that can be scanned only in one direction, arrange the moving stage and the laser such that the moving directions thereof are not the same, and synchronize the moving stage and the laser to thereby form the first scribe lines 21 having the desired bent shape. After this laser processing, cleaning for removal of processing residues and altered layer removal by the laser can be performed.

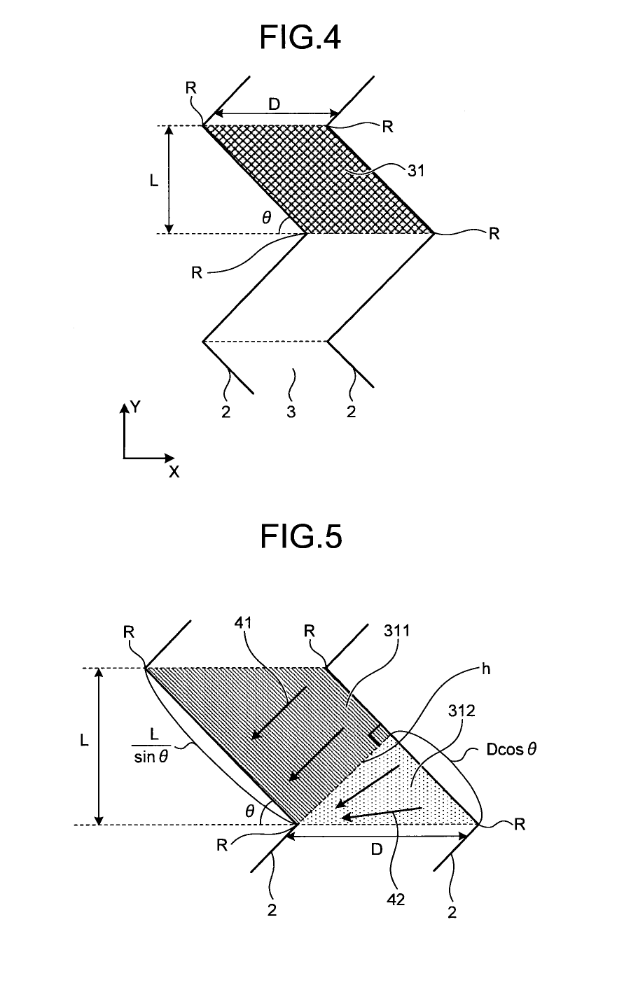

Thereafter, as shown in FIG. 3-3, the photoelectric conversion layer 12 is formed on the front surface electrode layer 11, in which the first scribe lines 21 are formed, by the CVD method. The intermediate conductor layer 13 is formed on the photoelectric conversion layer 12 by the sputtering method or the CVD method. Subsequently, as shown in FIG. 3-4, like the first scribe lines 21, the second scribe lines 22 for separating the intermediate conductor layer 13 and the photoelectric conversion layer 12 are formed by the laser processing method. Like the first scribe lines 21, the second scribe lines 22 have a bent shape in plan view and are formed at predetermined intervals in a specific direction. The second scribe lines 22 are formed in positions where the second scribe lines 22 do not overlap the first scribe lines 21. After this laser processing, cleaning for removal of processing residues and altered layer removal by the laser can be performed.

Thereafter, as shown in FIG. 3-5, the rear surface electrode layer 14 is formed on the intermediate conductor layer 13, in which the second scribe lines 22 are formed, by the sputtering method. At this point, the rear surface electrode layer 14 is embedded in the second scribe lines 22. Subsequently, as shown in FIG. 3-6, like the first scribe lines 21, the third scribe lines 23 for separating the rear surface electrode layer 14, the intermediate conductor layer 13, and the photoelectric conversion layer 12 are formed by the laser processing method. Like the first scribe lines 21, the third scribe lines 23 have a bent shape in plan view and are formed at predetermined intervals. The third scribe lines 23 are formed in positions where the third scribe lines 23 do not overlap the first scribe lines 21 and the second scribe lines 22. After this laser processing, cleaning for removal of processing residues and altered layer removal by the laser can be performed. As described above, the thin film solar cell shown in FIGS. 1 and 2 is manufactured.

The shape of the scribe lines 2 according to the first embodiment is explained below. FIG. 4 is a schematic diagram of an example of the shape of the scribe lines according to the first embodiment. In this figure, a left right direction in the paper surface is represented as an X direction corresponding to an extending direction of the upper side and the lower side of the insulated translucent substrate 10 shown in FIG. 1. A direction in the paper surface perpendicular to the X direction is represented as a Y direction corresponding to an extending direction of the right side and the left side of the insulated translucent substrate 10.

As shown in the figure, when a crossing angle with respect to the X direction is represented as θ, the scribe lines 2 are formed by alternately joining line segments having inclination of an angle θ and line segments having inclination of an angle −θ. In FIG. 4, the scribe lines 2 are formed in a zigzag shape. An interval in the X direction between the adjacent scribe lines 2 is represented as D and an interval in the Y direction between bending points R adjacent to each other on one scribe line 2 is represented as L. The unit solar battery cell 3 is divided into a parallelogram region 31 having a bottom side D and height L by a line segment in the X direction connecting the bending points R having the same phase of the adjacent two scribe lines 2, a line segment in the X direction connecting bending points R adjacent to these bending points R and having the same phase of the scribe lines 2, and two line segments formed by the scribe lines 2 connecting the bending points R of these two line segments. The direction of electric currents in this parallelogram region 31 is examined.

A case that a relational expression of Formula (1) below is satisfied by the bottom side D and the height L of the parallelogram of the region 31 is considered. FIG. 5 is a schematic diagram of a state in which electric currents flow in a transparent electrode layer corresponding to a parallelogram region. Actually, the electric currents concentrate near bending points and a current path is not formed linearly and is widened and bent. Therefore, the following calculation is only an approximate calculation.

L/D sin θ·cos θ (1)

When the relation of Formula (1) is satisfied, as shown in FIG. 5, the region 31 is divided into two regions: a region 311 and a region 312 by a perpendicular line h drawn down from one bending point R of the parallelogram to a side forming the scribe line 2 opposed to the bending point R. At points in the region 311, electric currents flow in a direction 41 parallel to the perpendicular line h drawn down to the scribe line 2 in shortest distances to the scribe line 2. On the other hand, from points in the region 312, line segments connecting the points and the bending point R, which is a start point of the perpendicular line h, are shortest distances. Electric currents flow in a direction 42 toward the bending point R.

When the condition of Formula (1) is satisfied, and when an area in which distances to the scribe line 2 are in a range of x to x+dx in the region 31 is represented as dS, dS/dx can be represented by Formulas (2) and (3) below.

dS/dx=L/sin θ−x·{1/tan θ−(π/2−θ)} (when 0≦x≦D·sin θ) (2)

dS/dx =x·arcsin {(sin θ/x)(D·cos θ−\sqrt{x²−D²·sin² θ})}when D√sin θ<x≦D) (3)

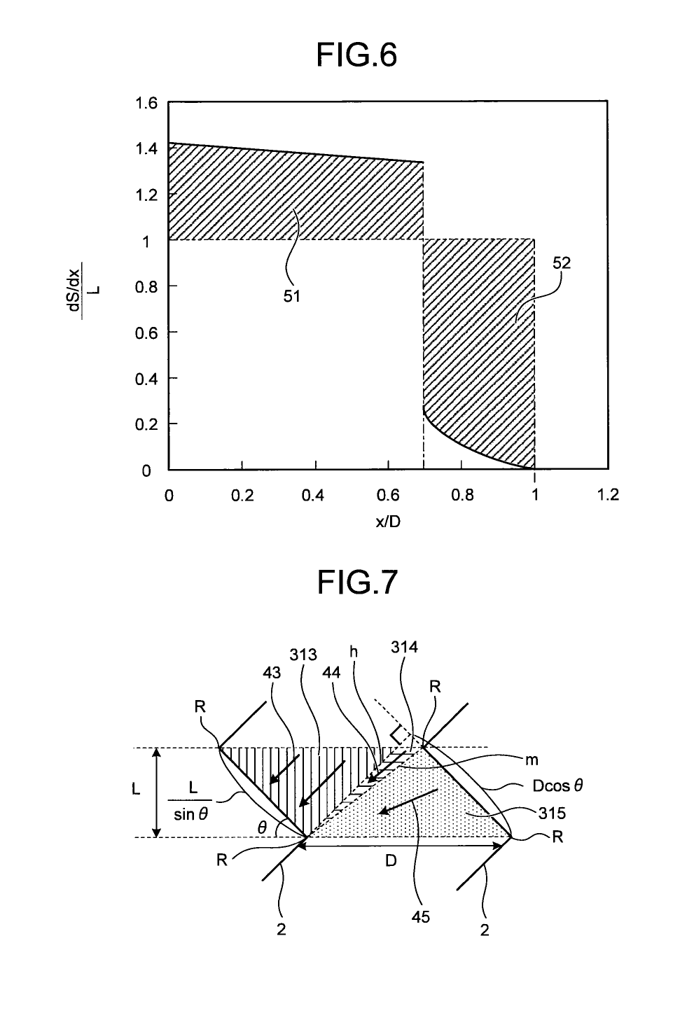

FIG. 6 is a graph of a relation between dS/dx and x respectively normalized by L and D when θ=π/4 and L/D=2. In this figure, the abscissa indicates distances x to the scribe lines 2 in positions in the region 31 normalized by a distance D between scribe lines 2 and the ordinate indicates a rate of change of an area S to the distance x normalized by a distance L in the Y direction between the bending points R.

When the scribe lines 2 are not bent unlike the scribe lines 2 shown in FIG. 1 and are scribed by straight lines parallel to sides of the insulated translucent substrate 10, as indicated by Formula (4) below, a relation between dS/dx and x is a straight line not depending on the distance x indicated by a broken line in FIG. 6 (a straight line parallel to the abscissa).

dS/dx=L (4)

When the scribe lines 2 are bent as shown in FIG. 1, a relation between dS/dx and x is a curved line indicated by a solid line. When the straight line and the curved line are compared, by bending the scribe lines 2, compared with the scribe lines 2 formed as the straight lines, a ratio of a region 51 having short distances to the scribe lines 2 increases and a ratio of a region 52 having long distances to the scribe lines 2 decreases. As a result, a ratio of an area having short distances to the scribe lines 2 increases as a whole and a current path is short. Compared with the scribe lines 2 formed as the straight lines, Joule losses can be reduced.

A case that a relational expression of Formula (5) below is satisfied by the bottom side D and the height L of the parallelogram of the region 31 is considered. FIG. 7 is a schematic diagram of a state in which electric currents flow in a transparent electrode layer corresponding to a parallelogram region. In FIG. 7, as in FIG. 5, actually, the electric currents concentrate near bending points and a current path is not formed linearly and is widened and bent. Therefore, the following calculation is only an approximate calculation.

L/D<sin θ·cos θ (5)

When the relation of Formula (5) is satisfied, as shown in FIG. 7, the region 31 is divided into three regions: a region 313, a region 314, and a region 315 by a perpendicular line h drawn down from one bending point R of the parallelogram onto an extended line of a side forming the scribe line 2 opposed to the bending point R and a diagonal line m connecting the bending point R from which the perpendicular line h is drawn down and the bending point R opposed to this bending point R. At points in the region 313, electric currents flow in a direction 43 parallel to the perpendicular line h drawn down onto the extended line of the scribe line 2. On the other hand, at points in the region 314 and the region 315, electric currents flow in directions 44 and 45 toward the bending point R from which the perpendicular line h is drawn down.

When the condition of Formula (5) is satisfied, and when an area in which distances to the scribe lines 2 are in a range of x to x+dx in the region 31 is represented as dS, dS/dx can be represented by Formulas (6) to (8) below.

dS/dx=L/sin θ−x·{1/tan θ−(π/2−θ)} when 0≦x≦D·sin θ) (6)

dS/dx=x·arcsin(L/x) (when L/cos θ≦x≦\sqrt{D²+L²/sin² θ−2L/tan θ}) (7)

dS/dx=x·arcsin{(sin θ/x)(D·cos θ−\sqrt{x²−D²·cos² θ})}(when \sqrt{D²+L²/sin² θ−2L/tan θ}≦x≦D) (8)

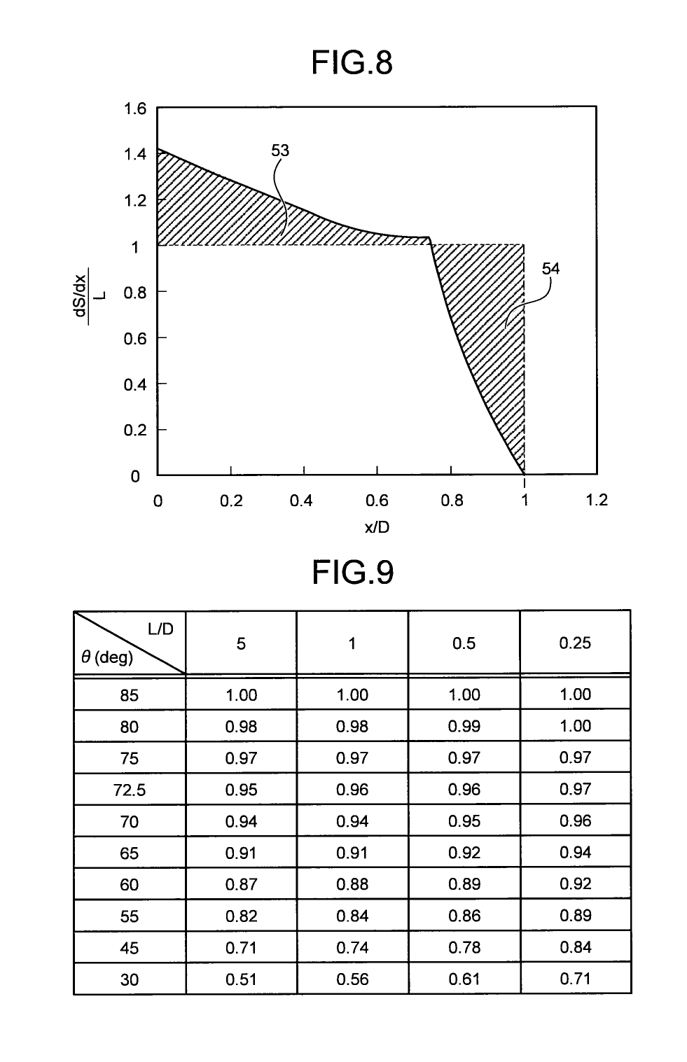

FIG. 8 is a graph of a relation between dS/dx and x respectively normalized by L and D when θ=π/4 and L/D=1/3. In this figure, the abscissa indicates distances x to the scribe lines 2 at positions in the region 31 normalized by a distance D between scribe lines 2 and the ordinate indicates a rate of change of an area S to the distance x normalized by a distance L between the bending points R.

When the scribe lines 2 are not bent unlike the scribe lines 2 shown in FIG. 1 and are scribed by straight lines parallel to sides of the insulated translucent substrate 10, as indicated by Formula (9) below, a relation between dS/dx and x is a straight line not depending on the distance x indicated by a broken line in FIG. 8 (a straight line parallel to the abscissa).

dS/dx=L (9)

When the scribe lines 2 are bent as shown in FIG. 1, a relation between dS/dx and x is a curved line indicated by a solid line. When the straight line and the curved line are compared, by bending the scribe lines 2, compared with the scribe lines 2 formed as the straight lines, a ratio of a region 53 having a short current path increases and a ratio of a region 54 having a long current path decreases. As a result, a current path is short. Compared with the scribe lines 2 formed as the straight lines, Joule losses can be reduced.

In FIGS. 6 and 8, the examples are respectively shown as a value of θ and a value of L/D. However, Formulas (2), (6), and (7) are always larger than L without depending on the value of L/D as long as 0<θ<π/2 is satisfied. Therefore, a region where a current path is short increases. In other words, in general, by bending the scribe lines 2, compared with the scribe lines 2 formed as the straight lines, Joule losses can be reduced. In particular, the effect of the reduction of Joule losses can be increased by setting the angle θ as small as possible and setting the value of L/D large.

The length of the current path in the region 31 is integrated to estimate Joule losses. As explained above, actually, near bending points where electric currents concentrate, a current path is not formed to be the shortest line and is widened and bent. Therefore, the following calculation is only an approximate calculation. Current density J can be represented as indicated by Formula (10) below if the current density J is integrated using dS/dx.

J=∫₀^{D}x·(dS/dx)·dx (10)

Joule losses in the transparent electrode layer (the front surface electrode layer 11) can be calculated from the current density J of Formula (10) and the resistivity of the transparent electrode layer. However, when it is assumed that the current density J and the resistivity of the transparent electrode layer are uniform in a solar cell module, the Joule losses are proportional to the current density J. When an integrated value of the length of the current path in the region 31 obtained when the scribe lines 2 are not bent is represented as J₀, J₀ can be represented as indicated by Formula (11) below.

$${J}_{0} = \frac{1}{2} {LD}^{2} \qquad ( 11 )$$

A ratio J/J₀ of Joule losses in the case of bent scribe lines and the case of non-bent scribe lines is calculated using Formulas (2), (3), and (6) to (8). The ratio J/J₀ is calculated by changing θ in a range of 30° to 85° and setting L/D to 5, 1, 0.5, and 0.25. FIG. 9 is a diagram of an example of a relation of the ratio J/J₀ of Joule losses between the case of bent scribe lines and the case of non-bent scribe lines at the time when L/D and θ are changed. From FIG. 9, to reduce Joule losses by about 5% or more of Joule losses that occur when the scribe lines 2 are not bent, it is desirable to set θ to at least an angle smaller than 72.5°.

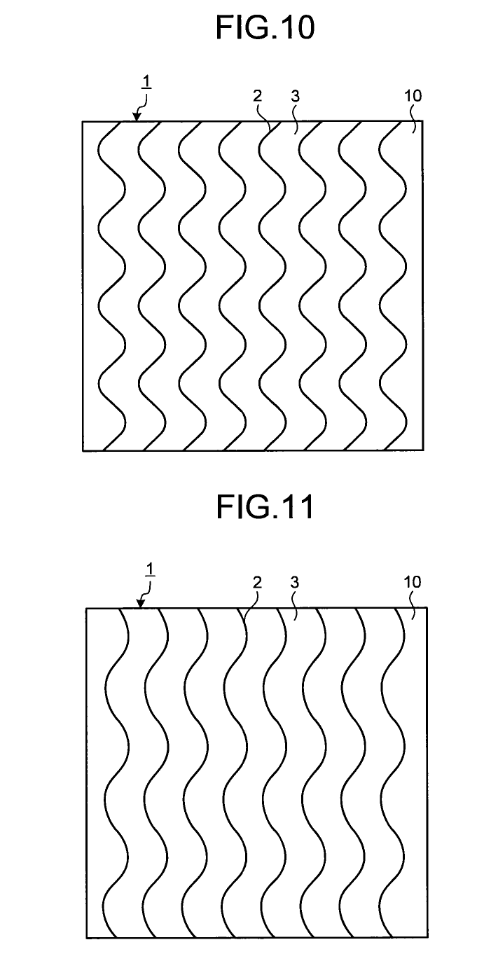

In the example explained above, a pattern of the scribe lines 2 has a shape pointed in the bending sections. However, the pattern of the scribe lines 2 is not limited to this. FIGS. 10 and 11 are top views of other examples of the configuration of the thin film solar cell according to the first embodiment. As shown in FIG. 10, the pattern of the scribe lines 2 can be a pattern rounded at corners of bending sections. As shown in FIG. 11, the pattern of the scribe lines 2 can be a wavy pattern (a pattern of a periodic wave shape). In these cases, there is an effect that it is possible to mitigate concentration of electric currents in the bending sections by increasing the curvature of the bending sections and to reduce Joule losses. In these cases, as in the above explanation, a distance between adjacent scribe lines 2 is fixed and the bending sections of the scribe lines 2 adjacent in a lateral direction are formed in substantially the same positions in the longitudinal direction.

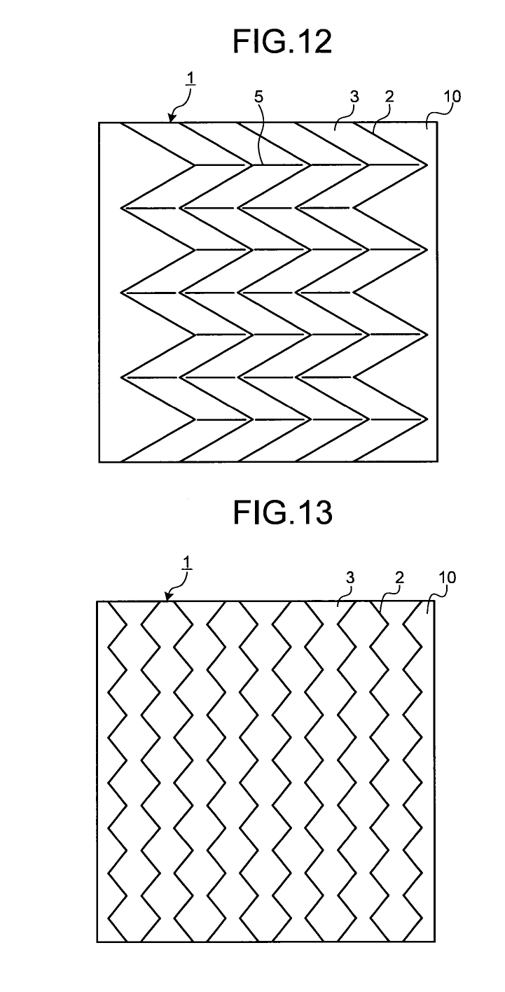

Further, in the example explained above, the unit solar battery cell 3 is periodically bent and formed in the shape meandering in a zigzag. However, the bending section can be only one place. The bent unit solar battery cell 3 can be divided into a plurality of regions in the longitudinal direction. FIG. 12 is a top view of another example of the thin film solar cell according to the first embodiment. As shown in FIG. 12, a plurality of collecting electrodes 5 having a thin line shape can be arranged in the lateral direction of the unit solar battery cell 3 between the insulated translucent substrate 10 and the front surface electrode layer 11. When the collecting electrodes 5 are arranged near the bending sections of the scribe lines 2, electric currents in a region where the path in the front surface electrode layer 11 is the longest can be led to the collecting electrodes 5. Consequently, it is possible to further reduce Joule losses in the front surface electrode layer 11. As a material forming the collecting electrodes 5, it is desirable to use silver, aluminum, gold, chrome, nickel, titanium, or the like, which is a metal material having high electric conductivity compared with a transparent conductive material forming the front surface electrode layer 11.

According to the first embodiment, the scribe lines 2 are bent with respect to the sides of the insulated translucent substrate 10. Therefore, the current path in the front surface electrode layer 11 formed of the transparent conductive material is slanted with respect to the width direction of the unit solar battery cell 3 and the current path can be reduced. As a result, there is an effect that it is possible to reduce Joule losses and improve power generation efficiency compared with Joule losses that occur when the cell width of the unit solar battery cell 3 formed by not bending the scribe lines 2 is set same.

When the area of the unit solar battery cell 3 is the same, if the unit solar battery cell 3 is formed in a meandering shape, the length is increased in a direction along the meandering and the width in a direction orthogonal to the meandering direction is reduced. Therefore, it is also possible to consider that the current path is short and losses can be reduced.

Further, the separation grooves on both the sides of the unit solar battery cell 3 are formed in the same meandering shapes that overlap when the separation grooves are translated in the specific direction. The unit solar battery cell 3 held between the separation grooves is formed in the meandering shape such that the width in the specific direction is substantially fixed. Therefore, a section where the width is large is not formed. Consequently, a section where a current path is long is not formed.

On the other hand, for example, when the unit solar battery cell 3 held between separation grooves meandering at random is considered, a partially constricted narrow section and a wide section are formed. In the narrow section, a current path is short and, on the other hand, in the wide section, a current path is long and losses increases. In other words, from the viewpoint of a reduction in losses, when an average of the widths of the unit solar battery cell 3 is the same, it is more desirable to substantially fix the width of the unit solar battery cell 3 in all positions as in the first embodiment than to form the wide section and the partially constricted section.

According to the first embodiment, the positions in the longitudinal direction of the bending sections in the scribe lines 2 are set in substantially the same positions in all the scribe lines 2. Therefore, the width of the unit solar battery cell 3 is substantially fixed. As a result, because there is no region where a current path is extremely long, there is also an effect that Joule losses can be reduced.

Further, crossing angles of the scribe lines 2 with respect to the direction perpendicular to the longitudinal direction (the lateral direction) of the scribe lines 2 are represented as θ and −θ, an absolute value of θ is set smaller than 72.5°, and a bending degree of the unit solar battery cells 3 is set large. Consequently, the effect of the reduction of the current path is increased. There is also an effect that it is possible to further reduce Joule losses in the front surface electrode layer 11 formed of the transparent conductive material.

When the unit solar battery cell 3 is caused to periodically meander, it is desirable that the ratio L/D of the half period L (the height L in FIG. 4) and the width D of the unit solar battery cell 3 (D in FIG. 4) is equal to or larger than 0.25. The current path tends to be able to be reduced as L/D is larger and θ is smaller. In other words, it is desirable to cause the unit solar battery cell 3 to meander to be largely crooked to some extent.

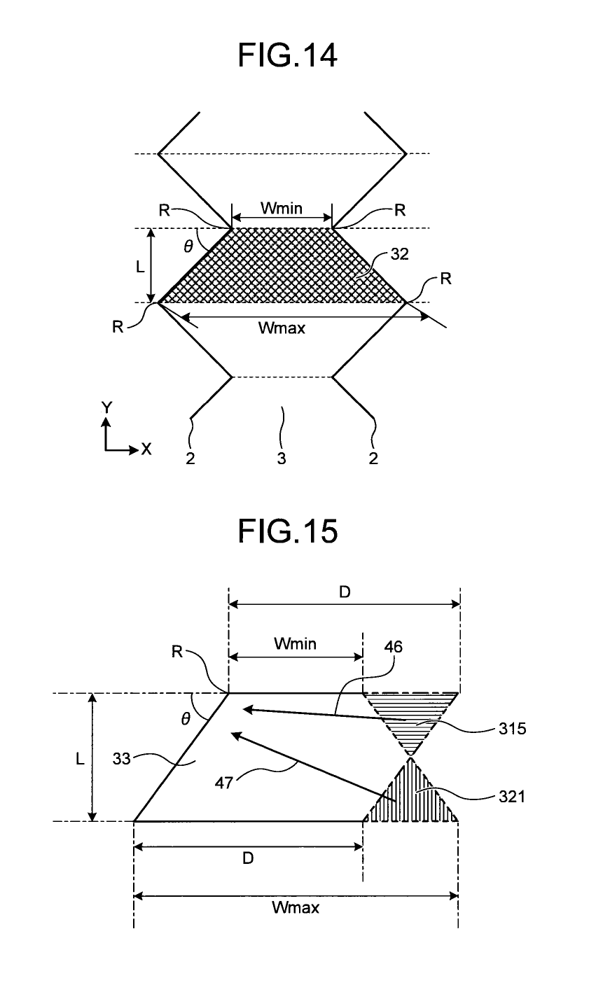

The thin film solar cell according to the first embodiment and the thin film solar cell according to Patent Literature 1 are compared. FIG. 13 is a schematic top view of the structure of the thin film solar cell according to Patent Literature 1. FIG. 14 is a schematic diagram of an example of the shape of the scribe lines according to Patent Literature 1. Components same as those in the first embodiment are denoted by the same reference numerals and signs.

As shown in FIG. 13, in the structure of the thin film solar cell according to Patent Literature 1, when the meandering scribe lines 2 (the separation grooves) are formed in a wavy shape, if the scribe lines 2 translate in a specific direction as in the first embodiment, the scribe lines 2 are not formed in shapes that overlap one another. The unit solar battery cell 3 is divided by one meandering wavy scribe line 2 and the wavy scribe line 2 having a phase reversed with respect to this scribe line 2. Therefore, the length in the lateral direction (the specific direction) of the unit solar battery cell 3 is different depending on a place and periodically changes.

In FIG. 14, a left right direction in the paper surface is represented as an X direction corresponding to an extending direction of the upper side and the lower side of the insulated translucent substrate 10 shown in FIG. 13. A direction in the paper surface perpendicular to the X direction is represented as a Y direction corresponding to an extending direction of the right side and the left side of the insulated translucent substrate 10. In Patent Literature 1, a maximum interval, a minimum interval, and an average interval between the scribe lines 2 adjacent to each other are respectively represented as Wₘₐₓ, Wₘᵢₙ, and Wₐᵥₑ. As in the first embodiment, a crossing angle of the scribe lines 2 with respect to the X direction is represented as θ and an interval in the Y direction between the bending points R adjacent to each other on the same scribe line 2 is represented as L. In Patent Literature 1, the phases of the two scribe lines 2 adjacent to each other are opposite. Therefore, the width of the unit solar battery cell 3 surrounded by the adjacent two scribe lines 2 gradually decreases from a section where the interval between the bending points R is the maximum interval Wₘₐₓ reaches a section where the interval between the bending points R is the minimum interval Wₘᵢₙ, gradually increases, and reaches a section where the interval between the bending points R is the maximum interval Wₘₐₓ.

The unit solar battery cell 3 is divided into a region 32 of a trapezoid having the upper side Wₘₐₓ, the lower side Wₘᵢₙ, and the height L by a line segment in which the interval between the bending points R is the maximum interval Wₘₐₓ, a line segment that is adjacent to the bending points R having the maximum interval Wₘₐₓ and in which the interval between the bending points R is the minimum interval Wₘᵢₙ, and two line segments formed by the scribe lines 2 connecting the bending points R of these two line segments. Concerning a current path in this trapezoidal region 32, the Patent Literature 1 and the first embodiment are compared and examined on condition that Formula (12) below in which the average width of the unit solar battery cell 3 in Patent Literature 1 is equal to that in the first embodiment holds.

$$D = {W}_{ave} = \frac{{W}_{ma x} + {W}_{m i n}}{2} \qquad ( 12 )$$

In Patent Literature 1, a relation of Formula (13) below holds among L, θ, Wₘₐₓ, and Wₘᵢₙ.

$$tan θ = \frac{2 L}{( {W}_{ma x} + {W}_{m i n} )} \qquad ( 13 )$$

Because Wₘₐₓ and Wₘᵢₙ are positive values, a relation of Inequality (14) below holds. From Formulas (13) and (14), a relation of Inequality (15) below holds.

$$\begin{matrix}( {W}_{ma x} - {W}_{m i n} ) < 2 D & ( 14 ) \\ tan θ > \frac{L}{D} ( when 0 < θ < 90 ° ) & ( 15 )\end{matrix}$$

In a range of 0°<θ<90°, tan θ is a monotone increasing function of θ. As explained above, the effect of the reduction of Joule losses can be increased by setting the angle θ as small as possible and setting a value of L/D large. However, in Patent Literature 1, because a relation among θ, L, and D needs to satisfy the relation of Formula (15), there is a limit in setting the angle θ as small as possible and setting the value of L/D large.

Patent Literature 1 and the first embodiment are compared on condition that Formula (15) is satisfied and values of θ, L, and D in Patent Literature 1 and the first embodiment are the same. FIG. 15 is a schematic diagram of comparison of a state in which electric currents flow in a transparent electrode layer corresponding to a trapezoidal region of the thin film solar cell according to Patent Literature 1 and a state in which electric currents flow in a transparent electrode layer corresponding to a parallelogram region of the thin film solar cell according to the first embodiment. In FIG. 15, the parallelogram region 31 shown in FIG. 4 in the first embodiment and the trapezoidal region 32 shown in FIG. 14 in Patent Literature 1 serving as a comparative example are superimposed one on top of the other and compared.

A difference does not occur in current paths in the transparent electrode layers of electric currents generated in a region 33 where both the regions 31 and 32 overlap. A difference between current paths in the transparent electrode layers of electric currents generated in a region 315 and a region 321 where both the regions 31 and 32 do not overlap is a difference in Joule losses. The electric currents generated in the regions 315 and 321 flow toward an intersection of a perpendicular line drawn down to the scribe line 2 or toward the bending point R such that the current paths of the electric currents are the shortest with respect to the scribe line 2. When a current path 46 in the transparent electrode layer of the electric currents generated in the region 315 and a current path 47 in the transparent electrode layer of the electric currents generated in the region 321 are compared, it is obvious from FIG. 15 that the current path 46 is short compared with the current path 47. In other words, Joule losses can be reduced more in the first embodiment than in Patent Literature 1.

Consequently, when Patent Literature 1 and the first embodiment are compared, even when the values of θ, L, and D in Patent Literature 1 and the first embodiment are the same, Joule losses can be reduced more in the first embodiment. In the first embodiment, because there is no limit in a relation between values of θ and L/D, Joule losses can be further reduced by setting the angle θ as small as possible and setting the value of L/D large.

### Second Embodiment

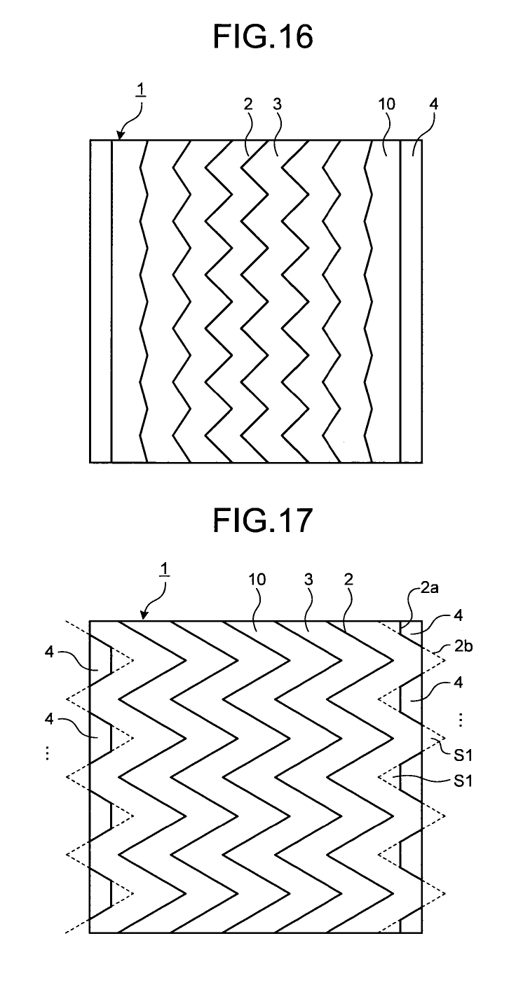

FIG. 16 is a top view of an example of a thin film solar cell according to the second embodiment of the present invention. In the configuration of the thin film solar cell 1 according to the second embodiment, the scribe lines 2 are arranged to have a smaller degree of bending from the center of the insulated translucent substrate 10 toward peripheral edges (ends) in the lateral direction of the scribe lines 2. In this example, the shape of the scribe lines 2 that separate the unit solar battery cells 3 and the current extracting sections 4 at both ends in the lateral direction is substantially parallel to end faces of the insulated translucent substrate 10. The scribe lines 2 adjacent to each other at the peripheral edges are not substantially parallel to each other because the degree of bending changes. However, the positions and the periods of peaks and valleys forming bending sections are aligned. Consequently, it is possible to suppress formation of a region where an amount of change in the width of the unit solar battery cell 3 is extremely large. Components same as those in the first embodiment are denoted by the same reference numerals and signs and explanation of the components is omitted. A sectional structure of the thin film solar cell 1 having such structure and a method of manufacturing the thin film solar cell 1 are the same as those in the first embodiment. Therefore, explanation of the sectional structure and the manufacturing method is omitted as well.

Degrees of bending of the scribe lines 2 and intervals among the scribe lines 2 are desirably adjusted such that generated current amounts of the unit solar battery cells 3 are substantially equal. Concerning a pattern of the scribe lines 2, as in the first embodiment, a pattern rounded at corners of bending sections or a wavy pattern can be used.

According to the second embodiment, there is an effect that it is possible to reduce an area of the current extracting sections 4, which do not contribute to power generation, at both the ends of the insulated translucent substrate 10 and improve a power generation efficiency of a thin film solar cell module. Because electrodes of the unit solar battery cells 3 at both the ends are generally liner, it is easy to connect, to the electrodes, a bus wire for extracting electric power to the outside of the module.

In the unit solar battery cells 3 at the peripheral edges of the insulated translucent substrate 10, a current path in the front surface electrode layer 11 formed of the transparent conducive material is long because the scribe lines 2 are not substantially parallel. Therefore, Joule losses could increase. However, in the unit solar battery cells 3 in sections other than the peripheral edges of the insulated translucent substrate 10, because Joule losses are reduced, a Joule loss amount of the solar cell module as a whole is reduced.

### Third Embodiment

FIG. 17 is a top view of an example of a thin film solar cell according to a third embodiment of the present invention. In the thin film solar cell 1 according to the third embodiment, a degree of bending of the scribe lines 2 does not change at the peripheral edges (ends) in the lateral direction of the scribe lines 2. If it is attempted to set the scribe lines 2 in endmost sections substantially in parallel to the scribe lines 2 adjacent thereto, the scribe lines 2 protrude from the insulated translucent substrate 10. Therefore, bending sections of the scribe lines 2 in the endmost sections protruding from the insulated translucent substrate 10 are set parallel to the end faces of the insulated translucent substrate 10 to fit in the insulated translucent substrate 10. The shape of the scribe lines 2 is changed such that the unit solar battery cells 3 arranged at both ends in a left right direction in the figure (the lateral direction of the scribe line 2) have an area substantially equal to the area of the other unit solar battery cells 3.

For example, when the shape of a scribe line 2a on the rightmost side is set the same as the shape of the other scribe lines 2, the shape of the scribe line 2a is the shape of a scribe line 2b indicated by a dotted line. However, in this case, a part of the scribe line 2b is formed outside a forming region of the insulated translucent substrate 10. As a result, the area of the unit solar battery cell 3 at the rightmost side is smaller than the area of the other unit solar battery cells 3 by an area S1 per one bending section projecting to the right. Therefore, the shape of bending sections on a side opposed to imaginary bending sections formed outside the region of the insulated translucent substrate 10 is changed to a shape indicated by the scribe line 2a. This shape is obtained by taking the area S1 away from the electrode extracting section 4. Bending sections on the left side of the scribe line 2a are omitted. Sides forming the bending sections are connected by straight lines halfway in the bending sections. Consequently, the current extracting section 4 is separated into a plurality of island-shaped regions.

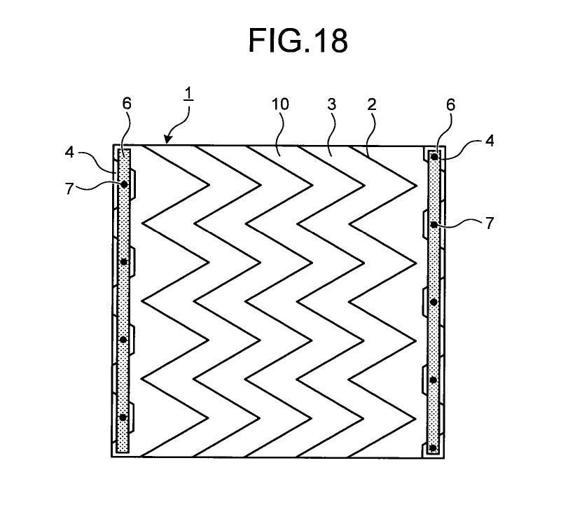

FIG. 18 is a schematic top view of an example of a configuration for extracting an electric current from the thin film solar cell shown in FIG. 17. In this thin film solar cell 1, bus wires 6 are provided on regions including the electrode extracting sections 4 at both ends in a left right direction of the figure. The electrode extracting sections 4 formed in an island-shape and the bus wires are electrically connected by connecting sections 7. As the material of the bus wires 6, a wire material having low resistance such as copper or aluminum can be used. Solder can be applied to the surfaces of the bus wires 6 to improve connectivity to the rear surface electrode layer 14.

Because the electrode extracting sections 4 are arranged in the island shape, the bus wires 6 are also provided on the unit solar battery cells 3 present between the electrode extracting sections 4. Therefore, the bus wires 6 are likely to come into contact with the rear surface electrode layer 14 of the unit solar battery cells 3 in the outermost edges to be short circuited. Therefore, it is desirable to insert insulation sheets between the rear surface electrode layer 14 of the unit solar battery cells 3 and the bus wires 6 or cover the top surfaces of the bus wires 6 with insulating films. Further, as an electric connection method for the rear surface electrode layer 14 of the electrode extracting sections 4 and the bus wires 6, it is desirable to use solder connection, ultrasonic welding, or a bonding method in which a conductive adhesive or an anisotropic conductive sheet is used.

Same components as those in the first embodiment are denoted by the same reference numerals and signs and explanation of the components is omitted. A sectional structure of the thin film solar cell 1 having such structure and a method of manufacturing the thin film solar cell 1 are the same as those in the first embodiment. Therefore, explanation of the sectional structure and the manufacturing method is omitted as well.

Further, concerning a pattern of the scribe lines 2, as in the first embodiment, a pattern rounded at corners of bending sections or a wavy pattern can be used. As in the second embodiment, the scribe lines 2 can be formed to have a smaller degree of bending from the center of the insulated translucent substrate 10 toward the peripheral edges (ends) in the lateral direction of the scribe lines 2. In a state in which a degree of bending of the scribe lines 2 at the outermost edges is set small to some extent, bending sections of the scribe lines 2 at the outermost ends protruding from the insulated translucent substrate 10 can be set parallel to the end faces of the insulated translucent substrate 10. Further, as in the first embodiment, a plurality of collecting electrodes having a thin line shape can be arranged in the lateral direction of the unit solar battery cell 3 between the insulated translucent substrate 10 and the front surface electrode layer 11.

In the third embodiment, even in the unit solar battery cells 3 at the peripheral edges (ends) in an array direction of the scribe lines 2 (the lateral direction of the unit solar battery cells 3), it is possible to reduce the area of the current extracting sections 4, which do not contribute to power generation, at both the ends of the insulated translucent substrate 10 without reducing a bending degree of the scribe lines 2. As a result, there is an effect that it is possible to improve a power generation efficiency of a thin film solar cell module.

In the embodiments explained above, a superstrate structure including the insulated translucent substrate is explained. However, the same effect can be obtained when the same shape of the unit solar battery cells 3 is used for a substrate structure in which a reflection electrode, a photoelectric conversion layer, and a transparent electrode are stacked in order on a substrate and light is made incident from a film surface side. Connection of the reflection electrode and the transparent electrode in the grooves can be performed by any one of the electrodes. However, the connection can be performed via another conductive material such as conductive paste.

### INDUSTRIAL APPLICABILITY

As explained above, the thin film solar cell according to the present invention is useful for a structure in which a plurality of unit solar battery cells are connected in series on a substrate.

### REFERENCE SIGNS LIST

1 THIN FILM SOLAR CELL

2 SCRIBE LINES

3 UNIT SOLAR BATTERY CELLS

4 CURRENT EXTRACTING SECTIONS

5 COLLECTING ELECTRODES

6 BUS WIRES

7 CONNECTING SECTIONS

10 INSULATED TRANSLUCENT SUBSTRATE

11 FRONT SURFACE ELECTRODE LAYER

12 PHOTOELECTRIC CONVERSION LAYER

13 INTERMEDIATE CONDUCTOR LAYER

14 REAR SURFACE ELECTRODE LAYER

21 FIRST SCRIBE LINE

22 SECOND SCRIBE LINE

23 THIRD SCRIBE LINE

1. A thin film solar cell comprising:
a first electrode layer formed of a transparent conductive material;
a photoelectric conversion layer; and
a second electrode layer including a conductive material that reflects light,
the first electrode layer, the photoelectric conversion layer, and the second electrode layer being formed on a substrate,
the thin film solar cell including a plurality of unit cells divided by grooves, and
the second electrode layer and the first electrode layer of the unit cell adjacent to the second electrode layer being connected in the groove formed in the photoelectric conversion layer and the unit cells being electrically connected in series, wherein
the grooves on both sides of at least one of the unit cells are formed such that the unit cell held between the grooves meanders while having fixed width in a predetermined direction and have same shapes that overlap when the grooves translate in the predetermined direction.

2. The thin film solar cell according to claim 1, wherein the groove has a structure in which a groove formed by a first line segment crossing at an angle θ with respect to the predetermined direction and a groove formed by a second line segment crossing at an angle −θ with respect to the predetermined direction are connected to have at least one bending section.

3. The thin film solar cell according to claim 1, wherein the bending section of the groove is formed by a curved line.

4. The thin film solar cell according to claim 1, wherein the groove is formed by a periodically wavy curved line.

5. The thin film solar cell according to claim 1, wherein
the substrate has a rectangular shape,
the predetermined direction is parallel to a first side of the substrate, and
the grooves are periodically provided in an extending direction of the first side and arranged such that positions of bending sections on an extending direction of a second side crossing the first side of the substrate or positions of peaks and valleys of the bending sections substantially coincide with one another.

6. The thin film solar cell according to claim 1, wherein an absolute value of the angle θ is an angle smaller than 72.5°.

7. The thin film solar cell according to claim 1, further comprising a collecting electrode having a thin line shape, the collecting electrode being arranged near a bending section of the groove between the substrate and the first electrode layer.

8. The thin film solar cell according to claim 1, wherein a degree of bending of the groove becomes smaller from a center in the predetermined direction of the substrate toward an end of the substrate.

9. The thin film solar cell according to claim 8, wherein
the substrate has a rectangular shape,
the predetermined direction is parallel to a first side of the substrate, and
the groove formed at an end in an extending direction of the first side of the substrate is a straight line substantially parallel to an extending direction of a second side crossing the first side of the substrate.

10. The thin film solar cell according to claim 1, wherein
laminated structures of the first electrode layer, the photoelectric conversion layer, and the second electrode layer at both ends in the predetermined direction of the substrate are current extracting sections for extracting, to an outside, an electric current generated by the unit cells connected in series, and
the thin film solar cell further comprises:
wires provided on the current extracting sections; and
connecting sections that electrically connect the wires and the current extracting sections.

11. The thin film solar cell according to claim 10, wherein
the current extracting sections have structure in which the current extracting sections are separated into a plurality of island shapes in an extending direction of the grooves by bending structures of the unit cells at both the ends in the predetermined direction of the substrate, and
the connecting sections are provided in the current extracting sections.

12. The thin film solar cell according to claim 1, wherein the photoelectric conversion layer has structure in which a plurality of semiconductor layers including pn junctions or pin junctions having different band gaps are stacked in a direction perpendicular to a substrate surface.

13. A method of manufacturing a thin film solar cell comprising:
forming a first electrode layer on a substrate;
separating, with first separation grooves having a bent shape parallel to one another, the first electrode layer for each of unit cells;
forming a photoelectric conversion layer including a semiconductor layer on the substrate on which the first electrode layer is formed;
separating, with second separation grooves having a shape same as the first separation grooves, the photoelectric conversion layer for each of the unit cells in positions different from the first separation grooves;
embedding a conductive material in the second separation grooves;
forming a second electrode layer on the photoelectric conversion layer including the conductive material embedded in the second separation grooves; and
separating, with third separation grooves having a shape same as the first separation grooves, the second electrode layer and the photoelectric conversion layer for each of the unit cells in positions different from the first and second separation grooves.
